(19) United States
(12) Patent Application Publication
(10) Pub. No.: US 2016/0093553 A1
(43) Pub. Date: Mar. 31, 2016

(54) ON DEMAND COOLING OF AN NVM USING A PELTIER DEVICE

(71) Applicants: Mani Prakash, University Place, WA (US); William A. Samaras, Olympia, WA (US)

(72) Inventors: Mani Prakash, University Place, WA (US); William A. Samaras, Olympia, WA (US)

(21) Appl. No.: 14/496,791

(22) Filed: Sep. 25, 2014

(51) Int. Cl. H01L 23/38; G11C 5/02

(52) U.S. Cl. CPC H01L 23/38; G11C 5/02

(57) ABSTRACT

Some examples relate to an electronic system that includes a substrate and a non-volatile memory (NVM) mounted on the substrate. The electronic system further includes a Peltier device mounted to a portion of the NVM to provide on demand short term cooling to the NVM during operation of the NVM. Other examples relate to a method that includes operating a plurality non-volatile memories (NVMs) that is part of an electronic system, and using a plurality of Peltier devices to provide on demand short term cooling to a portion of each NVM.

### TECHNICAL FIELD

Embodiments described herein generally relate to cooling a non-volatile memory (NVM), and more particularly to on demand cooling of an NVM using a Peltier device.

### BACKGROUND

Non-volatile memory (NVM) is typically utilized to provide high capacity memory. As an example NVM is commonly incorporated into in a (Dual Inline Memory Module) DIMM form factor.

A DIMM will conventionally have multiple NVM devices in order to deliver the needed memory capacity. When NVM's are mixed with conventional silicon technologies (e.g., CPU's, chipsets) in a system, traditional cooling methods (e.g., heat spreaders) might not be sufficient to prevent NVM memory throttling due to the difficulty of maintaining the lower silicon junction temperature for the NVM's.

All types of silicon chips have a maximum junction temperature under which they need to operate. Many silicon chips, including memory chips, have a trigger based on temperature to ‘throttle’ back the activity in the silicon chip when the temperature reaches predefined limit related to junction temperature. When that happens, there is a performance loss for the silicon chip. When the thermal environment gets better, the silicon chip reverts back to full performance.

In addition, even if only a specific NVM (or a few NVM's) in a DIMM that includes multiple NVMs exceeds it's (their) silicon junction temperature limit, throttling may be triggered with the NVM(s) resulting is performance loss.

One known thermal solution for a DIMM that includes multiple NVM's is to utilize a heat spreader system for all the NVM devices on the DIMM. However, when utilizing a conventional heat spreader system there is the potential for the DIMM to trigger throttling resulting in performance loss even if one of the NVM devices gets to its silicon junction temperature limit.

Throttling is usually triggered because the heat spreader system cannot react fast enough (e.g., by increasing fan speeds) to provide adequate short term cooling. The thermal time constants of existing heat spreader systems are quite large in comparison to electrical devices switching times.

Therefore, a need exists for an on demand, very short time constant cooling mechanism for the individual NVM's in a DIMM that include one or more NVM's. Providing as needed on demand, very short time constant cooling mechanism may mitigate excessive short duty cycle thermal excursions.

Mitigating excessive short duty cycle thermal excursions may diminish the potential for throttling by not permitting the NVM from ever getting to the throttling trigger temperature limits, especially when multiple NVM's are configured in a DIMM factor. The response time to mitigate temperature excursions needs to be orders of magnitude faster than the traditional method of speeding up system fans that are currently used to provide more NVM cooling.

### BRIEF DESCRIPTION OF THE DRAWINGS

FIG. 1 shows an example electronic system that includes an NVM which can receive on demand short term cooling from a Peltier device.

FIG. 2 shows the electronic system of FIG. 1 where the electronic system includes multiple Peltier devices which can provide on demand short term cooling to multiple portions of the NVM.

FIG. 3 shows the electronic system of FIG. 2 where the electronic system further includes a control that selectively activates one or more of the multiple Peltier devices.

FIG. 4 shows an example electronic system that includes a plurality of NVMs which can each receive on demand short term cooling from a respective Peltier device.

FIG. 5 shows the electronic system of FIG. 4 where each NVM in the electronic system includes multiple Peltier devices which can provide on demand short term cooling to multiple portions of each NVM.

FIG. 6 shows the electronic system of FIG. 5 where the electronic system further includes a control that selectively activates one or more of the multiple Peltier devices.

FIG. 7 shows the front side of a DIMM that includes multiple NVMs in an example electronic system.

FIG. 8 shows the back side of the DIMM shown in FIG. 7.

FIG. 9 illustrates a flow diagram of an example method of providing on demand cooling of an NVM using a Peltier device.

FIG. 10 illustrates a flow diagram of another example method of providing on demand cooling to a plurality of NVMs using a plurality of Peltier devices.

FIG. 11 is a block diagram of an electronic device incorporating at least one electronic system and/or method described herein.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Orientation terminology, such as “horizontal,” as used in this application is defined with respect to a plane parallel to the conventional plane or surface of a wafer or substrate, regardless of the orientation of the wafer or substrate. The term “vertical” refers to a direction perpendicular to the horizontal as defined above. Prepositions, such as “on,” “side” (as in “sidewall”), “higher,” “lower,” “over,” and “under” are defined with respect to the conventional plane or surface being on the top surface of the wafer or substrate, regardless of the orientation of the wafer or substrate.

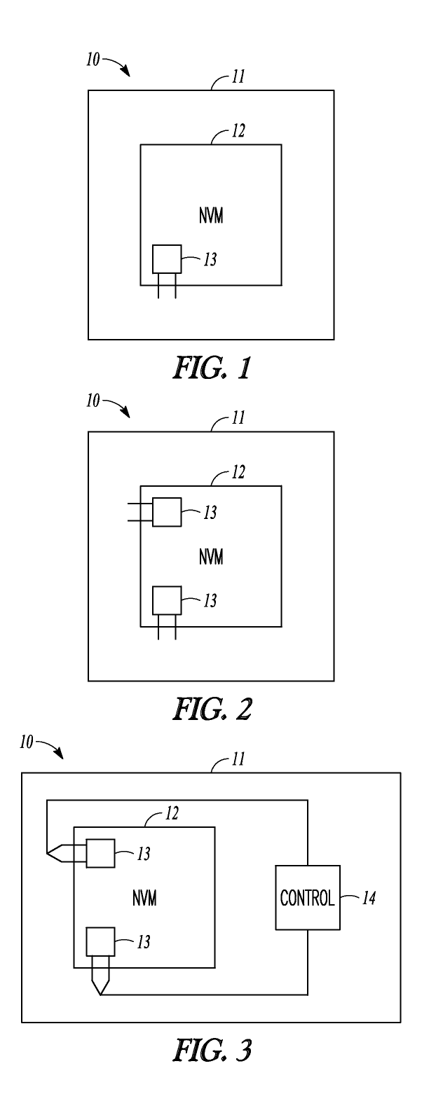

FIG. 1 shows an example electronic system 10 that includes an NVM 12 mounted on a substrate 11. The NVM 12 may receive on demand short term cooling from a Peltier device 13. A Peltier device is a thermoelectric device which may provide heating or cooling to the components depending on the polarity of the current that is run through the Peltier device.

The use of the Peltier device 13 may miniaturize the size of the cooling mechanism. As an example, the Peltier device 13 may be a thin film Peltier device that may provide on demand short term cooling to a very low wattage NVM 12 to prevent the NVM 12 from ever reaching a silicon junction temperature that may cause unwanted throttling.

The Peltier device 13 may be activated so that the silicon junction temperature of the NVM remains low enough to prevent throttling. The temperature of the NVM 12 may drop much faster than using other known techniques (e.g., speeding up system fans). The Peltier device 13 may be turned off at a preset temperature and in some forms, the on demand short term cooling provided by the Peltier device 13 may repeat as needed by the electronic system 10.

FIG. 2 shows the electronic system 10 of FIG. 1 where the electronic system 10 includes at least one additional Peltier device 13 mounted to different portions of the NVM 12 to provide on demand short term cooling to the NVM 12 during operation of the NVM 12. Forms of the electronic system 10 are contemplated where the electronic system 10 includes any number of Peltier devices 13. The Peltier devices 13 may be located at different portions of the NVM 12 where there is (i) anticipated elevated silicon junction temperatures may occur in the NVM 12; and/or (ii) a predicted level of memory activity based on the design of the electronic system 10.

FIG. 3 shows the electronic system 10 of FIG. 2 where the electronic system 10 includes further includes a control 14. In some example forms of the electronic system 10, the control 14 may (i) predict when one or more of the Peltier devices 13 are needed provide on demand short term cooling to the different portions of the NVM 12 and then activate the appropriate Peltier devices 13 to provide on demand short term cooling; and/or (ii) measure temperatures of the different portions of the NVM 12 and when one or portions of the NVM 12 require cooling based on the measure temperatures activate one or more of the Peltier devices 13 to provide on demand short term cooling to the different portions of the NVM 12.

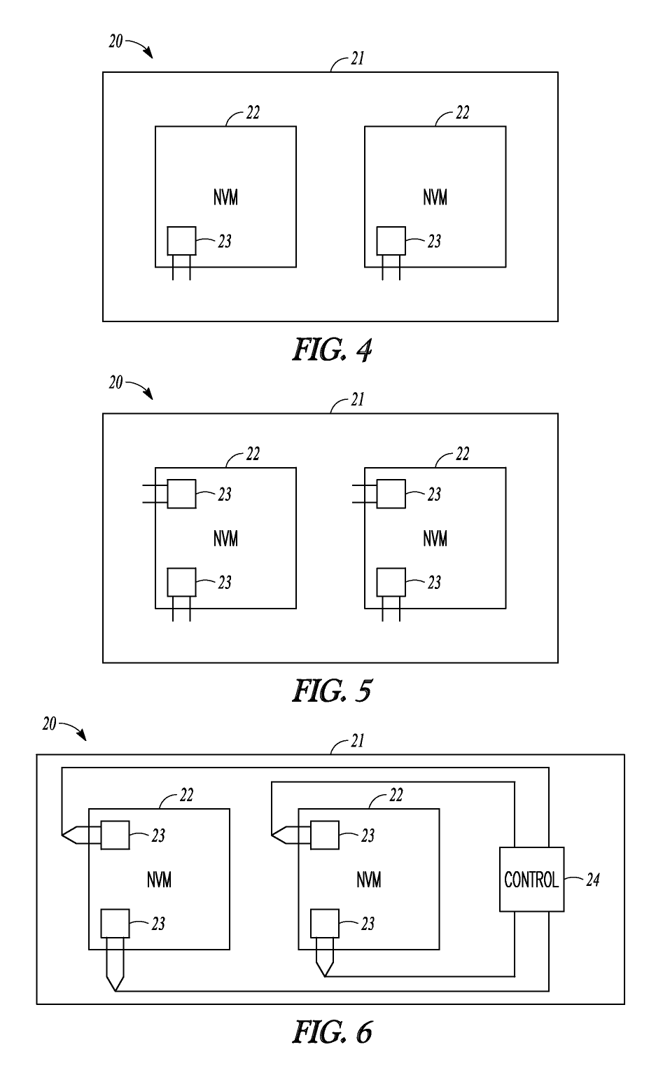

FIG. 4 shows another example electronic system 20 that includes a plurality of NVMs 22 mounted on a substrate 21. The electronic system 20 further includes a plurality of Peltier devices 23 such that each one of the plurality of NVMs 22 may receive on demand short term cooling from a respective Peltier device 23.

FIG. 5 shows the electronic system 20 of FIG. 4 where each NVM 22 in the electronic system 22 includes multiple Peltier devices 23. As an example, the multiple Peltier devices 23 may provide on demand short term cooling to multiple portions of some, or all of the NVMs 22.

FIG. 6 shows the electronic system 20 of FIG. 5 where the electronic system further includes a control 24 that selectively activates one or more of the multiple Peltier devices 23. In some example forms of the electronic system 20, the control 24 may (i) predict when one or more of the Peltier devices 23 are needed provide on demand short term cooling to the different portions of the respective NVMs 22 and then activate the appropriate Peltier devices 23 to provide on demand short term cooling; and/or (ii) measure temperatures of the different portions of the respective NVMs 22 and when one or more portions of the NVMs 22 require cooling based on the measure temperatures activate one or more of the Peltier devices 23 to provide on demand short term cooling to the different portions of the NVMs 22.

Example forms of the electronic system 20 are contemplated where at least one (or more) of the NVMs 22 includes at least one additional Peltier device such that a plurality of Peltier devices 22 may be mounted to different portions of the at least one NVM 22 to provide on demand short term cooling to different portions of the at least one NVM 22 during operation of the at least one NVM 22. In addition, example forms of the electronic system 20 are contemplated where each NVM 22 includes at least one additional Peltier device 23 such that a plurality of Peltier devices 23 may be mounted to different portions of each NVM 22 to provide on demand short term cooling to different portions of each NVM 22 during operation of each NVM 22.

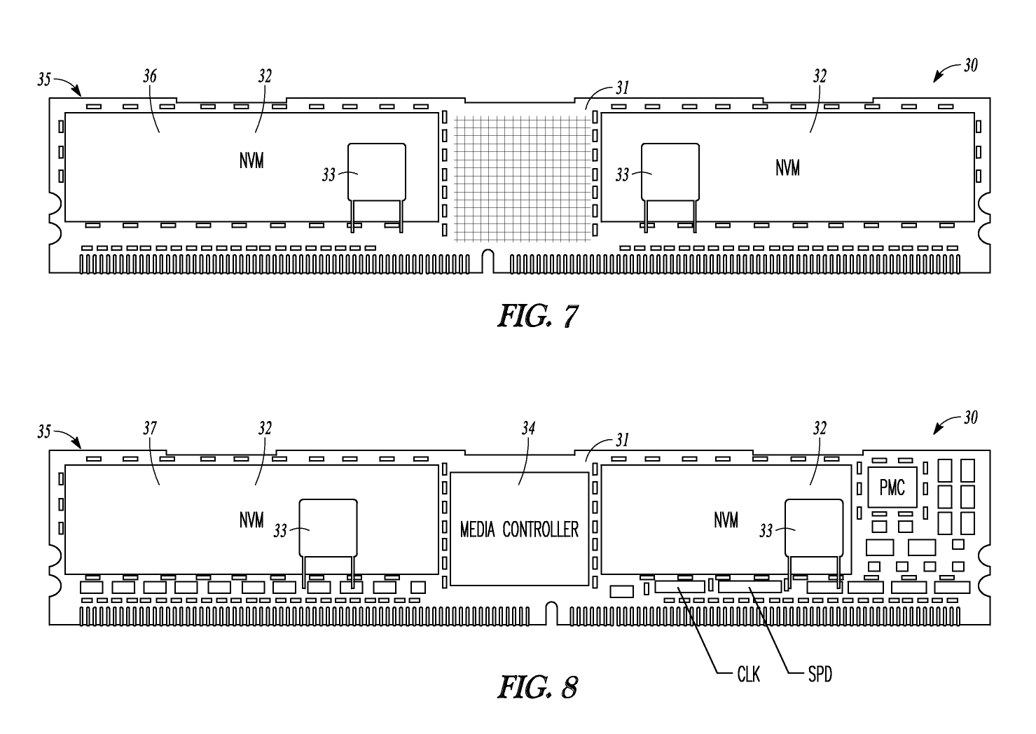

FIG. 7 shows a DIMM form factor electronic component 35 that includes multiple NVMs 32 mounted on a front side of a substrate 31 in an example electronic system 30. FIG. 8 shows the back side of the DIMM form factor electronic component 35 shown in FIG. 7 where multiple NVMs 32 are mounted on a back side 37 of the substrate 31.

As shown in FIGS. 7 and 8, the electronic system 30 may further include a control 34. The control 34 may predict when one or more of the Peltier devices 33 are needed provide on demand short term cooling to the different portions of the respective NVMs 32 and then activate the appropriate Peltier devices 33 to provide on demand short term cooling. In addition, or alternatively, the control 34 may measure temperatures of the different portions of the respective NVMs 32 and when one or portions of the NVMs 32 require cooling based on the measure temperatures activate one or more of the Peltier devices 33 to provide on demand short term cooling to the different portions of the NVMs 32. It should be noted that the control 34 may provide on demand short term cooling to the different portions of the NVMs 32 based on a variety of factors that are known now or discovered in the future.

The electronic systems and methods described herein may provide on-demand, instantaneous short term cooling to NVM devices with corresponding quick response times that reduce temperature and potentially eliminate the need for throttling. As an example, the NVM cooling that may be provided by the electronic systems and methods described herein may result in no performance loss for the DIMM form factor electronic component 35 shown in FIGS. 7 and 8.

The duration of the power increase from the Peltier device(s) 33 may be much smaller than the thermal time constant and may be relatively insignificant for the overall cooling of the DIMM form factor electronic component 35. The relatively short duration of the small power increase should not affect the overall thermal performance of any other electronic components that may be included in the electronic system 30.

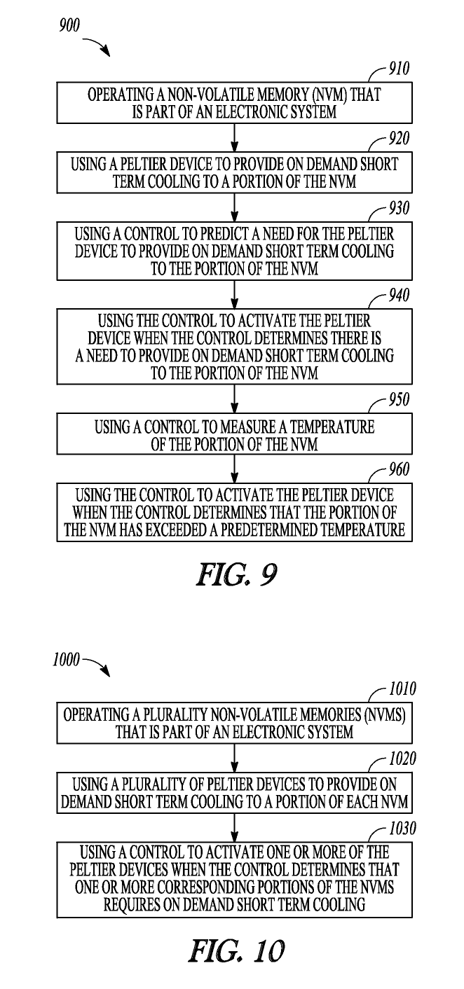

FIG. 9 illustrates a flow diagram of an example method [900]. FIGS. 1-3 show corresponding assemblies for portions of the method [900] shown in FIG. 9.

The method [900] includes [910] operating a non-volatile memory (NVM) 12 that is part of an electronic system 10 (see FIG. 1). The method [900] further includes [920] using a Peltier device 13 to provide on demand short term cooling to a portion of the NVM 12.

The method [900] may further include [930] using a control 14 to predict a need for the Peltier device 13 to provide on demand short term cooling to the portion of the NVM 12 and [940] using the control 14 to activate the Peltier device 13 when the control 14 determines there is a need to provide on demand short term cooling to the portion of the NVM 12. In addition, or alternatively, the method [900] may further include [950] using a control 14 to measure a temperature of the portion of the NVM 12, and [960] using the control 14 to activate the Peltier device 13 when the control 14 determines that the portion of the NVM 12 has exceeded a predetermined temperature.

FIG. 10 illustrates a flow diagram of another example method [1000]. FIGS. 4-8 show corresponding assemblies for portions of the method [1000] shown in FIG. 10.

The method [1000] includes [1010] operating a plurality non-volatile memories (NVMs) 22 that is part of an electronic system 20. The method [1000] further include [1020] using a plurality of Peltier devices 23 to provide on demand short term cooling to a portion of each NVM 22 (see FIGS. 4 and 5).

The method [1000] further includes [1020] using a control 24 to activate one or more of the Peltier devices 23 when the control 24 determines that one or more corresponding portions of the NVMs 22 requires on demand short term cooling. As an example, [1020] using a plurality of Peltier devices 23 to provide on demand short term cooling to a portion of each NVM 22 may include using the plurality of Peltier devices 23 to provide on demand short term cooling to multiple portions of each NVM 22.

In some example forms of the method [1000], [1010] operating a plurality (NVMs) 32 that is part of an electronic system 30 may include operating a plurality NVMs 32 that is part of DIMM factor electronic component 35 (see FIGS. 7 and 8). In addition, operating a plurality of NVMs 32 that is part of DIMM factor electronic component 35 may include operating a plurality NVMs 32 that are located on both sides 36, 37 of the DIMM factor electronic component 35.

Therefore, the electronic package 10 and methods describe herein may provide on-demand, instantaneous short term cooling to NVM devices. The quick response times of the electronic package 10 and methods describe herein may reduce temperature long enough to prevent throttling.

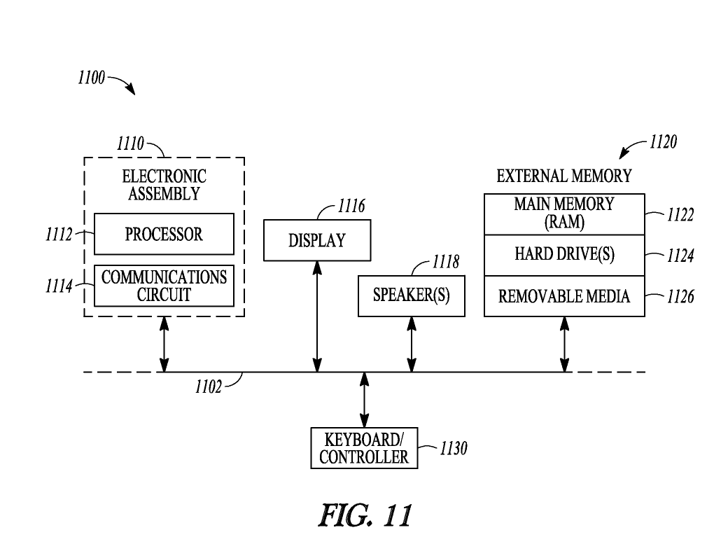

An example of a higher level application for the electronic systems and methods as described herein is shown in FIG. 11. FIG. 11 is a block diagram of an electronic apparatus 1100 incorporating at least one electronic system and/or method described herein.

Electronic apparatus 1100 is merely one example of an electronic apparatus in which the electronic systems and methods as described herein may be used. Examples of electronic apparatuses 1100 include, but are not limited to personal computers, tablet computers, mobile telephones, game devices, MP3 or other digital music players, etc. In this example, electronic apparatus 1100 comprises a data processing system that includes a system bus 1102 to couple the various components of the apparatus. System bus 1102 provides communications links among the various components of the electronic apparatus 1100 and can be implemented as a single bus, as a combination of busses, or in any other suitable manner.

An electronic system 1110 is coupled to system bus 1102. The electronic system 1110 may include any circuit or combination of circuits. In one embodiment, the electronic system 1110 may include a processor 1112 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic system 1110 are a custom circuit, an application-specific integrated circuit (ASIC), or the like, such as, for example, one or more circuits (such as a communications circuit 1114) for use in wireless devices like mobile telephones, tablet computers, laptop computers, two-way radios, and similar electronic apparatuses. The IC can perform any other type of function.

The electronic apparatus 1000 can also include an external memory 1120, which in turn can include one or more memory elements suitable to the particular application, such as a main memory 1122 in the form of random access memory (RAM), one or more hard drives 1124, and/or one or more drives that handle removable media 1126 such as compact disks (CD), flash memory cards, digital video disk (DVD), and the like.

The electronic apparatus 1000 can also include a display device 1116, one or more speakers 1118, and a keyboard and/or controller 1130, which can include a mouse, trackball, touch screen, voice-recognition device, or any other device that permits a system user to input information into and receive information from the electronic apparatus 1000.

To better illustrate the method and apparatuses disclosed herein, a non-limiting list of examples is provided here:

Example 1 includes an electronic system that includes a substrate and a non-volatile memory (NVM) mounted on the substrate. The electronic system further includes a Peltier device mounted to a portion of the NVM to provide on demand short term cooling to the NVM during operation of the NVM.

Example 2 includes the electronic system of example 1, wherein at least one additional Peltier device is mounted to different portions of the NVM to provide on demand short term cooling to the NVM during operation of the NVM.

Example 3 includes the electronic system of any one of examples 1-2, further comprising a control that predicts when one or more of the Peltier devices are needed provide on demand short term cooling to the different portions of the NVM and then activates the appropriate Peltier device to provide on demand short term cooling.

Example 4 includes the electronic system of any one of examples 1-3, further comprising a control that measures temperatures of the different portions of the NVM and when one or portions of the NVM require cooling based on the measure temperatures, the controller may activate one or more of the Peltier devices to provide on demand short term cooling to the different portions of the NVM.

Example 5 includes the electronic system of any one of examples 1-4, and further including at least one additional NVM mounted on the substrate and at least one additional Peltier device, wherein a Peltier device is mounted to a portion of each additional NVM to provide cooling to each additional NVM during operation of the respective NVM.

Example 6 includes the electronic system of any one of examples 1-5, and further including a control that predicts when one or more of the Peltier devices are needed provide on demand short term cooling to the portion of the respective NVMs and then activates the appropriate Peltier device to provide on demand short term cooling.

Example 7 includes the electronic system of any one of examples 1-6, and further including a control that measures temperatures of the portion of each respective NVM and when one or the respective portions of the NVMs require cooling based on the measured temperatures, the controller may activate one or more of the Peltier devices to provide on demand short term cooling to the respective portions of the NVM.

Example 8 includes the electronic system of any one of examples 1-7, wherein at least one of the non-volatile memories (NVMs) includes at least one additional Peltier device such that a plurality of Peltier devices are mounted to different portions of the at least one NVM to provide on demand short term cooling to different portions of the at least one NVM during operation of the at least one NVM.

Example 9 includes the electronic package of any one of examples 1-8, wherein each NVM includes at least one additional Peltier device such that a plurality of Peltier devices are mounted to different portions of each NVM to provide on demand short term cooling to different portions of each NVM during operation of each NVM.

Example 10 the electronic package of any one of examples 1-9, wherein the plurality of NVMs and the substrate are part of a DIMM form factor electronic component.

Example 11 includes the electronic package of any one of examples 1-10, wherein at least one NVM is mounted to a front side of the DIMM form factor electronic component and at least one NVM is mounted to a back side of the DIMM form factor electronic component.

Example 12 includes the electronic package of any one of examples 1-11, and further including a control that predicts when one or more of the Peltier devices are needed provide on demand short term cooling to the different portions of the respective NVMs and then activates the appropriate Peltier device to provide on demand short term cooling.

Example 13 includes a method that includes operating a non-volatile memory (NVM) that is part of an electronic system and using a Peltier device to provide on demand short term cooling to a portion of the NVM.

Example 14 includes the method of example 13, and further including using a control to predict a need for the Peltier device to provide on demand short term cooling to the portion of the NVM, and using the control to activate the Peltier device when the control determines there is a need to provide on demand short term cooling to the portion of the NVM.

Example 15 includes the method of any one of examples 13-14, and further including using a control to measure a temperature of the portion of the NVM, and using the control to activate the Peltier device when the control determines that the portion of the NVM has exceeded a predetermined temperature.

Example 16 includes a method that includes operating a plurality non-volatile memories (NVMs) that is part of an electronic system, and using a plurality of Peltier devices to provide on demand short term cooling to a portion of each NVM.

Example 17 includes the method of any one of examples 16, and further including using a control to activate one or more of the Peltier devices when the control determines that one or more corresponding portions of the NVMs requires on demand short term cooling.

Example 18 includes the method of examples 16-17, wherein using a plurality of Peltier devices to provide on demand short term cooling to a portion of each NVM includes using the plurality of Peltier devices to provide on demand short term cooling to multiple portions of each NVM.

Example 19 includes the method of any one of examples 16-18, wherein operating a plurality non-volatile memories (NVMs) that is part of an electronic system includes operating a plurality non-volatile memories (NVMs) that is part of DIMM factor electronic component.

Example 20 includes the method of any one of examples 16-19, wherein operating a plurality non-volatile memories (NVMs) that is part of DIMM factor electronic component includes operating a plurality non-volatile memories (NVMs) that are located on both sides of the DIMM factor electronic component.

This overview is intended to provide non-limiting examples of the present subject matter—it is not intended to provide an exclusive or exhaustive explanation. The detailed description is included to provide further information about the methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description.

The Abstract is provided to comply with 37 C.F.R. §1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An electronic system, comprising:
a substrate; and
a non-volatile memory (NVM) mounted on the substrate; and
a Peltier device mounted to a portion of the NVM to provide on demand short term cooling to the NVM during operation of the NVM.

2. The electronic system of claim 1, further comprising at least one additional Peltier device is mounted to different portions of the NVM to provide on demand short term cooling to the NVM during operation of the NVM.

3. The electronic system of claim 2, further comprising a control that predicts when one or more of the Peltier devices are needed provide on demand short term cooling to the different portions of the NVM and then activates the appropriate Peltier device to provide on demand short term cooling.

4. The electronic system of claim 2, further comprising a control that measures temperatures of the different portions of the NVM and when one or portions of the NVM require cooling based on the measure temperatures, the controller may activate one or more of the Peltier devices to provide on demand short term cooling to the different portions of the NVM.

5. The electronic device of claim 1, further comprising:
at least one additional NVM mounted on the substrate; and
at least one additional Peltier device, wherein a Peltier device is mounted to a portion of each additional NVM to provide cooling to each additional NVM during operation of the respective NVM.

6. The electronic system of claim 5, further comprising a control that predicts when one or more of the Peltier devices are needed provide on demand short term cooling to the portion of the respective NVMs and then activates the appropriate Peltier device to provide on demand short term cooling.

7. The electronic system of claim 5, further comprising a control that measures temperatures of the portion of each respective NVM and when one or the respective portions of the NVMs require cooling based on the measured temperatures, the controller may activate one or more of the Peltier devices to provide on demand short term cooling to the respective portions of the NVM.

8. The electronic system of claim 5, wherein at least one of the non-volatile memories (NVMs) includes at least one additional Peltier device such that a plurality of Peltier devices are mounted to different portions of the at least one NVM to provide on demand short term cooling to different portions of the at least one NVM during operation of the at least one NVM.

9. The electronic system of claim 8, wherein each NVM includes at least one additional Peltier device such that a plurality of Peltier devices are mounted to different portions of each NVM to provide on demand short term cooling to different portions of each NVM during operation of each NVM.

10. The electronic system of claim 9, wherein the plurality of NVMs and the substrate are part of a DIMM form factor electronic component.

11. The electronic system of claim 10, wherein at least one NVM is mounted to a front side of the DIMM form factor electronic component and at least one NVM is mounted to a back side of the DIMM form factor electronic component.

12. The electronic system of claim 10, further comprising a control that predicts when one or more of the Peltier devices are needed provide on demand short term cooling to the different portions of the respective NVMs and then activates the appropriate Peltier device to provide on demand short term cooling.

13. A method, comprising:
operating a non-volatile memory (NVM) that is part of an electronic system; and
using a Peltier device to provide on demand short term cooling to a portion of the NVM.

14. The method of claim 13, further comprising:
using a control to predict a need for the Peltier device to provide on demand short term cooling to the portion of the NVM: and
using the control to activate the Peltier device when the control determines there is a need to provide on demand short term cooling to the portion of the NVM.

15. The method of claim 14, further comprising:
using a control to measure a temperature of the portion of the NVM; and
using the control to activate the Peltier device when the control determines that the portion of the NVM has exceeded a predetermined temperature.

16. A method, comprising:
operating a plurality non-volatile memories (NVMs) that is part of an electronic system; and
using a plurality of Peltier devices to provide on demand short term cooling to a portion of each NVM.

17. The method of claim 16, further comprising using a control to activate one or more of the Peltier devices when the control determines that one or more corresponding portions of the NVMs requires on demand short term cooling.

18. The method of claim 16, wherein using a plurality of Peltier devices to provide on demand short term cooling to a portion of each NVM includes using the plurality of Peltier devices to provide on demand short term cooling to multiple portions of each NVM.

19. The method of claim 16, wherein operating a plurality non-volatile memories (NVMs) that is part of an electronic system includes operating a plurality non-volatile memories (NVMs) that is part of DIMM factor electronic component.

20. The method of claim 19, wherein operating a plurality non-volatile memories (NVMs) that is part of DIMM factor electronic component includes operating a plurality non-volatile memories (NVMs) that are located on both sides of the DIMM factor electronic component.
